(19) United States
(12) Patent Application Publication
(10) Pub. No.: US 2014/0220777 A1
(43) Pub. Date: Aug. 7, 2014

(54) PROCESSING SYSTEM FOR COMBINED METAL DEPOSITION AND REFLOW ANNEAL FOR FORMING INTERCONNECT STRUCTURES

(71) Applicant: INTERNATIONAL BUSINESS MACHINES CORPORATION, (US)

(72) Inventors: Chih-Chao Yang, Glenmont, NY (US); Stephan A. Cohen, Wappingers Falls, NY (US); Joseph F. Maniscalco, Lake Katrine, NY (US)

(73) Assignee: INTERNATIONAL BUSINESS MACHINES CORPORATION, Armonk, NY (US)

(21) Appl. No.: 13/759,654

(22) Filed: Feb. 5, 2013

(51) Int. Cl. H01L 21/02

(52) U.S. Cl. CPC H01L 21/02697
USPC 438/653; 118/719

(57) ABSTRACT

An interconnect conductive metal used in forming an interconnect structure can be formed using a method in which deposition of a metal liner and a reflow anneal are performed in a same multi-chambered processing system without exposing the structure to air between the steps of deposition and reflow annealing. In the disclosure, an interconnect dielectric material including an opening is placed within the multi-chambered processing system and then the interconnect dielectric material is transferred, under vacuum, to a deposition chamber in which the metal liner is deposited. The interconnect dielectric material including the metal liner is then transferred, under the same vacuum, to an annealing chamber in which a reflow anneal is performed.

### BACKGROUND

The present disclosure relates to semiconductor device manufacturing. More particularly, the present disclosure relates to a method of forming an interconnect structure in which the interconnect conductive metal is formed by deposition of a metal liner and a reflow anneal which are performed in a same multi-chambered processing system without exposing the structure to air between the steps of deposition and reflow annealing. The present disclosure also provides a multi-chambered processing system in which the deposition and reflow anneal can be performed without breaking vacuum between the two processing steps.

Generally, semiconductor devices include a plurality of circuits that form an integrated circuit (IC) fabricated on a semiconductor substrate. A complex network of signal paths will normally be routed to connect the circuit elements distributed on the surface of the substrate. Efficient routing of these signals across the device requires formation of multilevel or multilayered schemes, such as, for example, single or dual damascene interconnect structures. The interconnect structure typically includes copper, Cu, or a Cu alloy since Cu-based interconnects provide higher speed signal transmission between large numbers of transistors on a complex semiconductor chip as compared with aluminum, Al,-based interconnects.

Within a typical interconnect structure, metal vias run perpendicular to the semiconductor substrate and metal lines run parallel to the semiconductor substrate. Further enhancement of the signal speed and reduction of signals in adjacent metal lines (known as “crosstalk”) is achieved in today's IC product chips by embedding the metal lines and metal vias (e.g., conductive features) in a dielectric material having a dielectric constant of less than 4.0.

During the formation of interconnect structures, the interconnect conductive metal, i.e., copper, is typically formed within an opening, e.g., line and/or via, which is present in an interconnect dielectric material, using a wet electrical-chemical plating (ECP) process. Prior to the ECP process, the open features are lined with a barrier liner and copper seed layer through a dry deposition process, e.g., physical vapor deposition (PVD), chemical vapor deposition (CVD), or atomic layer deposition (ALD). The ECP process is problematic from a chemical perspective. For example, the impurity levels in electroplated copper used for interconnect structures are: carbon, 100 parts per million (ppm), chlorine, 80 ppm, oxygen, 80 ppm, and sulfur, 50 ppm. At these impurity levels the conductivity of the copper interconnect can degrade beyond acceptable levels. Also, two different deposition steps, dry metal seed layer formation and wet ECP, are needed in the conventional processes flow which increase the time and cost of forming the interconnect structures.

In addition, and when small feature sizes (on the order of 50 nm or less) are subjected to the conventional processes, a portion of the opening that is formed into the interconnect dielectric material may remain unfilled. This may cause performance degradation as well as reliability related issues. As such, a method is needed that overcomes the above problems associated with ECP processes.

### SUMMARY

An interconnect conductive metal used in forming an interconnect structure can be formed using a method in which deposition of a metal liner and a reflow anneal are performed in a same multi-chambered processing system without exposing the structure to air between the steps of deposition and reflow annealing. In the disclosure, an interconnect dielectric material including an opening is placed within the multi-chambered processing system and then the interconnect dielectric material is transferred, under vacuum, to a deposition chamber in which the metal liner is deposited. The interconnect dielectric material including the metal liner is then transferred, under the same vacuum, to an annealing chamber in which a reflow anneal is performed.

In one aspect of the present disclosure, a method for forming an interconnect structure is provided. The method of the present disclosure includes providing an interconnect dielectric material having at least one opening. The interconnect dielectric material having the at least one opening is then placed within a multi-chambered processing system. Next, at least a metal liner comprising a conductive metal or conductive metal alloy is deposited above an uppermost surface of the interconnect dielectric material and in the at least one opening. In accordance with the present disclosure, the depositing of at least the metal liner is performed in a deposition chamber of the multi-chambered processing system. A reflow anneal is then performed within an annealing chamber of the multi-chambered processing system. In accordance with the present disclosure, the reflow anneal flows a portion of the metal liner located above the uppermost surface of the interconnect dielectric material into the at least one opening and fills the at least one opening with the conductive metal or conductive metal alloy. In accordance with the method of the present disclosure, a continuous vacuum is maintained during the depositing and the reflow anneal.

In another embodiment of the present disclosure, a processing system for forming interconnect structures is provided. The processing system of the present disclosure includes a loading/unloading chamber and a transfer chamber coupled to at least one deposition chamber and at least one annealing chamber, wherein the at least one deposition chamber is configured to deposit at least a metal liner comprising a conductive metal or conductive metal alloy above an uppermost surface of an interconnect dielectric material and in at least one opening present in the interconnect dielectric material, and the annealing chamber is configured to reflow the metal liner on the uppermost surface of the interconnect dielectric material and to fill the at least one opening with the conductive metal or conductive metal alloy. In accordance with the present disclosure, the processing system is configured to maintain a continuous vacuum during the depositing and reflow process.

### BRIEF DESCRIPTION OF THE DRAWINGS

FIG. 1 is a pictorial representation (through a cross sectional view) illustrating an initial structure including an interconnect dielectric material that can be employed in one embodiment of the present disclosure.

FIG. 2 is a pictorial representation (through a cross sectional view) illustrating the initial structure of FIG. 1 after forming an opening in the interconnect dielectric material.

FIG. 3 is a pictorial representation (through a cross sectional view) illustrating the structure of FIG. 2 after forming a diffusion barrier on exposed surfaces of the interconnect dielectric material.

FIG. 4 is a pictorial representation (through a cross sectional view) illustrating the structure of FIG. 3 after forming a metal liner comprising a conductive metal or conductive metal alloy on the diffusion barrier.

FIG. 5 is a pictorial representation (through a cross sectional view) illustrating the structure of FIG. 4 after formation of an interconnect conductive metal by performing a reflow anneal on the structure of FIG. 4 including the metal liner.

FIG. 6 is a schematic illustrating a top view diagram of a simplistic multi-chambered processing system that can be used in the present disclosure for forming at least the interconnect conductive metal shown in FIG. 5.

FIG. 7 is a schematic illustrating a top down diagram of a multi-chambered processing system that can be used in the present disclosure for depositing of the metal liner and performing the reflow anneal.

FIG. 8 is a flow diagram of one embodiment of the present disclosure for forming an interconnect structure using the multi-chambered processing system shown in FIG. 7.

FIG. 9 is a pictorial representation (through a cross sectional view) illustrating the structure of FIG. 5 after performing a planarization process.

### DETAILED DESCRIPTION

The present disclosure will now be described in greater detail by referring to the following discussion and drawings that accompany the present application. It is noted that the drawings of the present application are provided for illustrative purposes only and, as such, the drawings are not drawn to scale. In the following description, numerous specific details are set forth, such as particular structures, components, materials, dimensions, processing steps and techniques, in order to provide a thorough understanding of the present disclosure. However, it will be appreciated by one of ordinary skill in the art that the present disclosure may be practiced without these specific details. In other instances, well-known structures or processing steps have not been described in detail in order to avoid obscuring the present disclosure.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present.

In accordance with an embodiment of the present disclosure, a method for forming an interconnect structure is provided that uses a multi-chambered processing system in which at least the deposition of a metal liner and a subsequent reflow anneal are performed in the same tool without breaking vacuum between the deposition of the metal liner and the reflow anneal. In one embodiment, the method includes providing an interconnect dielectric material having at least one opening. The interconnect dielectric material is then placed within a multi-chambered processing system. Next, at least a metal liner comprising a conductive metal or conductive metal alloy is deposited above an uppermost surface of the interconnect dielectric material and in the at least one opening. The depositing of at least the metal liner is performed in a deposition chamber of the multi-chambered processing system. A reflow anneal is then performed within an annealing chamber of the multi-chambered processing system. The reflow anneal flows a portion of the metal liner located above the uppermost surface of the interconnect dielectric material into the at least one opening and fills the at least one opening with the conductive metal or conductive metal alloy. A continuous vacuum is maintained during the depositing and the reflow anneal.

The method of the present disclosure eliminates the need for copper electroplating. Moreover, the method of the present disclosure can reduce the overburden, lower the copper resistivity by lowering the amount of impurities present in the copper, and it is capable of completely filling the opening that is formed within the interconnect dielectric material. In addition, the method of the present disclosure, allows for the clean formation of a Cu/liner interface without air exposure or organic impurities being present. This in turn provides a reliable interconnect structure.

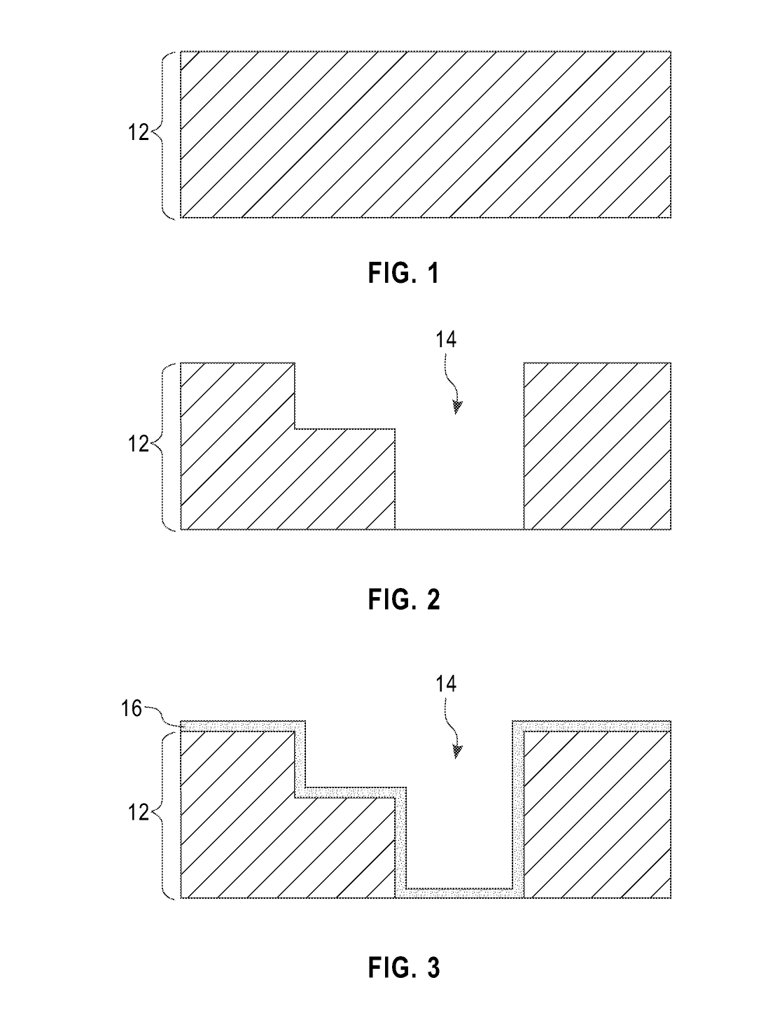

Referring first to FIG. 1, there is illustrated an initial structure that comprises an interconnect dielectric material 12 that can be employed in one embodiment of the present disclosure. Interconnect dielectric material 12 may be located upon a substrate (not shown in the drawings of the present application). The substrate, which is not shown, may comprise a semiconducting material, an insulating material, a conductive material or any combination thereof. When the substrate is comprised of a semiconducting material, any semiconducting material such as Si, SiGe, SiGeC, SiC, Ge alloys, GaAs, InAs, InP and other III/V or II/VI compound semiconductors may be used. In addition to these listed types of semiconducting materials, the present disclosure also contemplates cases in which the semiconductor substrate is a layered semiconductor such as, for example, Si/SiGe, Si/SiC, silicon-on-insulators (SOIs) or silicon germanium-on-insulators (SGOIs).

When the substrate is an insulating material, the insulating material can be an organic insulator, an inorganic insulator or a combination thereof including multilayers. When the substrate is a conducting material, the substrate may include, for example, polySi, an elemental metal, alloys of elemental metals, a metal silicide, a metal nitride or combinations thereof including multilayers. When the substrate comprises a semiconducting material, one or more semiconductor devices such as, for example, complementary metal oxide semiconductor (CMOS) devices can be fabricated thereon. When the substrate comprises a combination of an insulating material and a conductive material, the substrate may represent a lower interconnect level of a multilayered interconnect structure.

The interconnect dielectric material 12 can include any interlevel or intralevel dielectric including inorganic dielectrics or organic dielectrics. In one embodiment, the interconnect dielectric material 12 may be non-porous. In another embodiment, the interconnect dielectric material 12 may be porous. Porous dielectrics are advantageous since such dielectric materials when used as an interconnect dielectric material have lower dielectric constants than an equivalent non-porous dielectric material. Some examples of suitable dielectrics that can be used as the interconnect dielectric material 12 include, but are not limited to, SiO₂, silsesquioxanes, C doped oxides (i.e., organosilicates) that include atoms of Si, C, O and H, thermosetting polyarylene ethers, or multilayers thereof. When a multilayered interconnect dielectric material structure is employed, the various dielectric material layers are typically in direct contact with each other. The term “polyarylene” is used in this application to denote aryl moieties or inertly substituted aryl moieties which are linked together by bonds, fused rings, or inert linking groups such as, for example, oxygen, sulfur, sulfone, sulfoxide, carbonyl and the like.

In one embodiment, the interconnect dielectric material 12 has a dielectric constant that is about 4.0 or less. In another embodiment, the interconnect dielectric material 12 has a dielectric constant of about 2.8 or less. All dielectric constants mentioned herein are relative to a vacuum, unless otherwise noted. The interconnect dielectric material 12 that is employed in the present disclosure generally has a lower parasitic crosstalk as compared with dielectric materials that have a dielectric constant of greater than 4.0. The thickness of the interconnect dielectric material 12 may vary depending upon the dielectric material used as well as the exact number of dielectrics layers within the interconnect dielectric material 12. In one embodiment, and for normal interconnect structures, the interconnect dielectric material 12 has a thickness from about 50 nm to about 1000 nm. In other embodiments, the interconnect dielectric material 12 can have a thickness that is above or below the aforementioned range.

Referring now to FIG. 2, there is shown the initial structure of FIG. 1 after forming an opening 14 into the interconnect dielectric material 12. Although a single opening 14 is shown in the drawings, a plurality of such openings can be formed. When a plurality of openings are formed, each opening can have a same or a different depth. In some embodiments, the bottommost surface of the opening does not extend entirely through the interconnect dielectric material 12. In other embodiments, and as shown in FIG. 2, the opening 14 can extend entirely through the interconnect dielectric material 12. Also, and when a plurality of openings are formed, each opening 14 can be of a same type or of a different type.

The opening 14 can be formed into the interconnect dielectric material 12 utilizing lithography and etching. The lithographic process can include forming a photoresist (not shown) atop the interconnect dielectric material 12, exposing the photoresist to a desired pattern of radiation and developing the exposed photoresist utilizing a conventional resist developer. The pattern is then transferred into the underlying interconnect dielectric material 12 by etching. The etching can include a dry etching process (such as, for example, reactive ion etching, ion beam etching, plasma etching or laser ablation), and/or a wet chemical etching process. Typically, reactive ion etching is used in providing the opening 14. After patterning the underlying interconnect dielectric material 12, the patterned photoresist can be removed utilizing a conventional stripping process such as, for example, ashing.

In one embodiment and prior to patterning the interconnect dielectric material 12, a hard mask (not shown) can be formed directly on an uppermost surface of the interconnect dielectric material 12. When employed, the hard mask can include an oxide, a nitride, an oxynitride or any multilayered combination thereof. In one embodiment, the hard mask is an oxide such as silicon dioxide, while in another embodiment the hard mask is a nitride such as silicon nitride. The hard mask can be formed utilizing a conventional deposition process including, for example, chemical vapor deposition (CVD), plasma enhanced chemical vapor deposition (PECVD), chemical solution deposition, evaporation, and physical vapor deposition (PVD). Alternatively, the hard mask can be formed by one of thermal oxidation, and thermal nitridation.

When employed, the thickness of the hard mask is from 5 nm to 100 nm. Other thicknesses that are greater than or lesser than the thickness range mentioned above can also be employed for the hard mask. When a hard mask is present, a first etch is performed to transfer the pattern provided in the photoresist to the hard mask, the patterned photoresist is then removed by an ashing step, and thereafter, a second etch is performed to transfer the pattern from the patterned hard mask into the underlying interconnect dielectric material 12. In embodiments in which a hard mask is present, the hard mask can be removed from atop the interconnect dielectric material 12 after the opening 14 is formed therein.

The opening 14 that is formed into the interconnect dielectric material 12 can be a via opening, a line opening, and/or a combined via/line opening. In FIG. 2, and by way of an example, a combined via and line opening is shown. The individual via opening and line opening of the combined via and line opening are in communication with each other. When a combined via and line opening is formed, a second iteration of lithography and etching can be used in forming the same. A via opening can be distinguished from a line opening, in that a via opening has a width that is less than a width of the line opening.

Referring now to FIG. 3, there is illustrated the structure of FIG. 2 after forming a diffusion barrier 16 on all exposed surfaces of the structure including within the opening 14 (i.e., on sidewalls and the bottom wall of the opening) and along the uppermost surface of interconnect dielectric material 12. Diffusion barrier 16 can also be referred to as a liner which is contiguously present in the structure. The terms “contiguously” or “contiguous” denotes that the material liner or layer does not include any breaks therein.

The diffusion barrier 16 includes Co, Ir, Pt, Pd, Ta, Rh, TaN, Ti, TiN, Ru, RuN, RuTa, RuTaN, W, WN or any other material that can serve as a barrier to prevent a conductive material from diffusing there through. The thickness of the diffusion barrier 16 may vary depending on the deposition process used as well as the material employed. In one embodiment, the diffusion barrier 16 has a thickness from 2 nm to 50 nm. In another embodiment, the diffusion barrier 16 has a thickness from 5 nm to 20 nm.

The diffusion barrier 16 can be formed by a deposition process including, for example, chemical vapor deposition (CVD), plasma enhanced chemical vapor deposition (PECVD), atomic layer deposition (ALD), and physical vapor deposition (PVD). In some embodiments of the present disclosure, the diffusion barrier 16 can be formed by deposition using the multi-chambered processing system of the present disclosure.

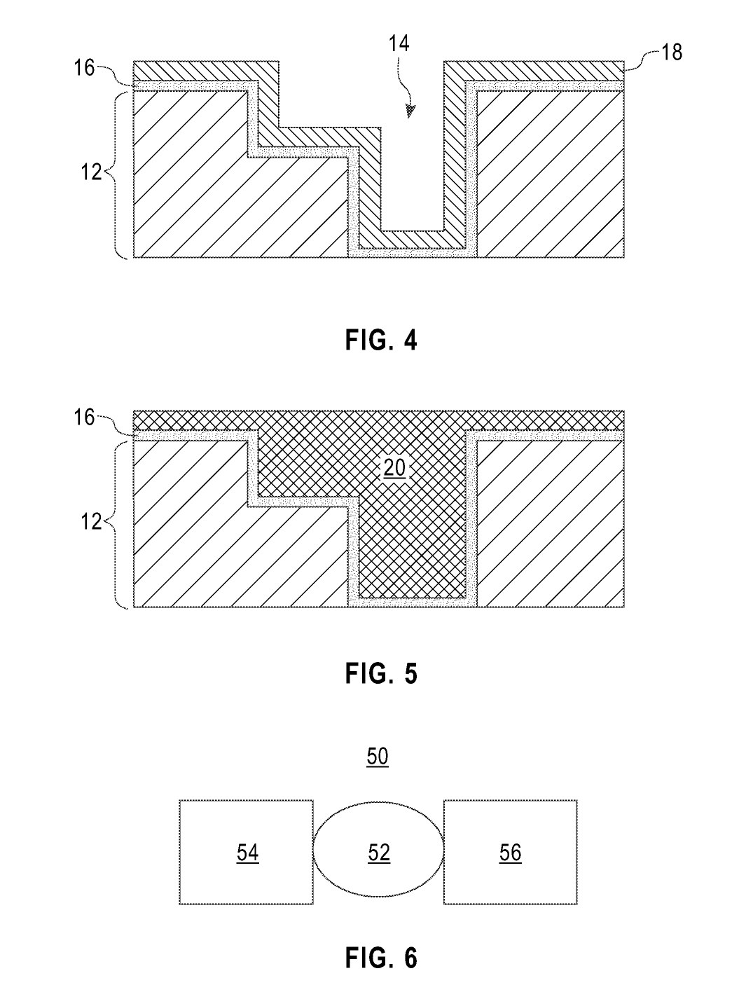

Referring now to FIG. 4, there is illustrated the structure of FIG. 3 after forming a metal liner 18 on an exposed uppermost surface of the diffusion barrier 16. As shown, metal liner 18 is within opening 14. The metal liner 18 may comprise a conductive metal or metal alloy. The metal liner 18 is used in the present disclosure in forming the conductive metal of an interconnect structure. As such, metal liner 18 may also be referred to herein as an interconnect conductive metal seed material. In one embodiment, the metal liner 18 may comprise Cu, a Cu alloy, Al, an Al alloy, W or a W alloy. In another embodiment, copper is employed as the metal liner 18. The metal liner 18 that is formed at this point of the present disclosure must be thick enough such that during a subsequent reflow anneal the opening 14 is completely filled with a conductive metal or metal alloy. As such, the thickness of the metal liner 18 is thicker on all horizontal surfaces of the structure than that on the vertical surfaces. In one embodiment of the present disclosure, metal liner 18 has a thickness from 2 nm to 80 nm.

The metal liner 18 can be formed by a physical vapor deposition process. Physical vapor deposition (PVD) is a method to deposit films by condensation of a vaporized form of the desired film material onto various surfaces. Physical vapor deposition (PVD) is a purely physical process such as high temperature vacuum evaporation with subsequent condensation, or plasma sputter bombardment rather than involving a chemical reaction at the surface to be coated as in chemical vapor deposition. In accordance with the present disclosure, the metal liner 18 is formed by PVD within one of the deposition chambers of the multi-chambered processing system of the present disclosure (to be described in greater detail herein below).

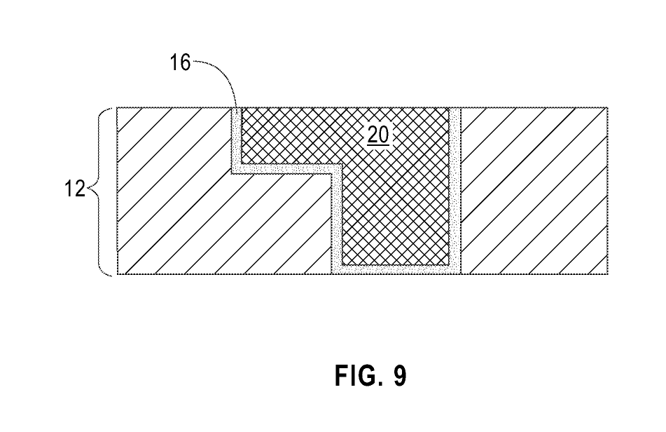

Referring now to FIG. 5, there is illustrated the structure of FIG. 4 after forming an interconnect conductive metal 20 by performing a reflow anneal on the metal liner 18. As shown, a portion of the interconnect conductive metal 20 can be located outside the opening 14, while another portion of the interconnect conductive metal 20 is located within the opening 14. Since the interconnect conductive metal 20 is comprised of the conductive metal or conductive metal alloy of the metal liner 18, the metal liner 18 is not separately shown in this drawing and in FIG. 9, which shows a further processing step of the present disclosure.

The formation of the interconnect conductive metal 20, which includes deposition of the metal liner 18 and a reflow anneal, is performed using the multi-chambered processing system of the present disclosure without breaking vacuum between those two steps. In some embodiments of the present disclosure, the deposition of the diffusion barrier 16, the metal liner 18 and reflow anneal are performed using the multi-chambered processing system of the present disclosure without breaking vacuum between the various deposition steps and the reflow anneal.

As stated above, the reflow anneal of the present disclosure is performed without breaking vacuum between at least the steps of metal liner 18 formation and reflow anneal. During the reflow anneal, a portion of the metal liner 18 that is located outside the opening 14 flows into the opening 14 filling at least a portion of the opening 14 with a conductive metal or conductive metal alloy.

In one embodiment, the reflow anneal can be performed at a temperature from 150° C. to 400° C. for a time period from 5 minutes to 500 minutes. In another embodiment, the reflow anneal can be performed at a temperature from 200° C. to 300° C. for a time period from 20 minutes to 100 minutes. In one embodiment, the reflow anneal is performed in a hydrogen-containing ambient. By “hydrogen-containing ambient” it is meant an environment that includes hydrogen. In another embodiment, the reflow anneal is performed in a nitrogen-containing ambient, i.e., an environment including nitrogen. In yet another embodiment, a combination of hydrogen and nitrogen can be used during the reflow anneal. Without wishing to be bound by any theory, it is believed that the during the reflow anneal, the surface energy of the structure is reduced in such a manner that a majority, but not all, of the metal liner 18 that is located outside the opening 14, i.e., on the field region of the structure, flows into the small features of the opening 14, and fills the opening 14 with a conductive metal.

Referring now to FIG. 6, there is illustrated a schematic top view diagram of a simplistic multi-chambered processing system 50 that can be used in the present disclosure for depositing at least the metal liner 18 and performing the reflow anneal without breaking a vacuum between the two processes, i.e., for forming the interconnect conductive metal 20. In some embodiments of the present disclosure, the multi-chambered processing system 50 can be used for depositing the diffusion barrier 16, the metal liner 18, and performing the reflow anneal without breaking vacuum between these various processing steps.

As shown in FIG. 6, the multi-chambered processing system 50 includes a loading/unloading chamber 52 coupled to at least one deposition chamber 54 and at least one annealing chamber 56. In accordance with the present disclosure, a sample is loaded into chamber 52 and then the system is locked and then evacuated to remove air. Once a desired pressure is reached, the sample is transferred from chamber 52 into at least one deposition chamber 54. Within the at least one deposition chamber 54, deposition of at least the metal liner 18, as described above, can be performed. In some embodiments of the present disclosure and prior to depositing the metal liner 18, the diffusion barrier 16, can be deposited with one of the deposition chambers of the multi-chambered processing system 50. After deposition of at least the metal liner 18, the sample including the deposited metal liner 18 is transferred from the at least one deposition chamber 54 to the at least one annealing chamber 56. Within the at least one annealing chamber 56, a reflow anneal, as described above, can be performed. After performing at least the reflow anneal within the at least one annealing chamber 56, the sample is transferred from the at least one annealing chamber 56 to the loading/unloading chamber 52 and thereafter the sample is removed from the multi-chambered processing system 50.

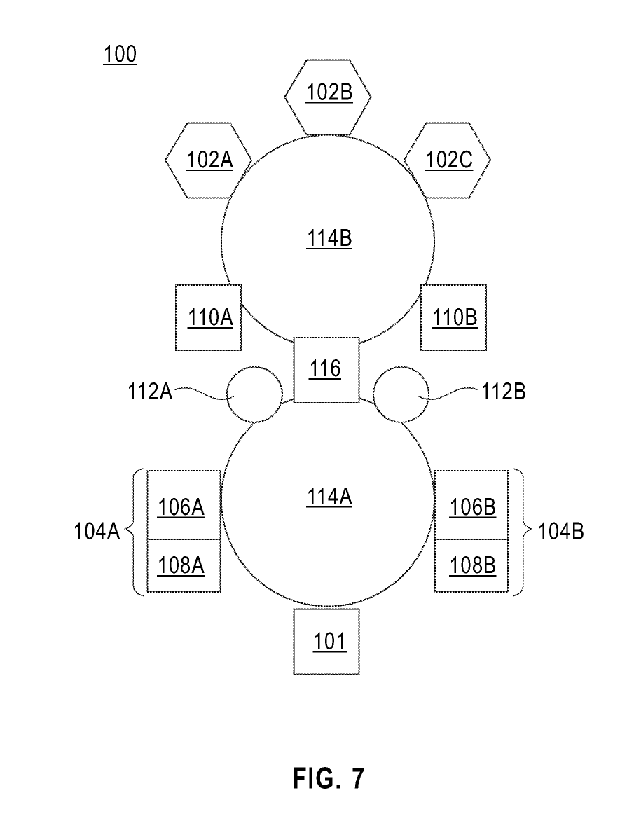

Reference is now made to FIG. 7, which is a schematic illustrating a top down diagram of a multi-chambered processing system 100 that can be used in the present disclosure for depositing at least the metal liner 18 and performing a reflow anneal without breaking a vacuum between the two processes. The multi-chambered processing system 100 shown in FIG. 7 includes various single wafer deposition chambers such as, for example, first deposition chamber 102A, second deposition chamber 102B, and third deposition chamber 102C, and multiple wafer annealing/cooling modules such as, for example, first annealing/cooling module 104A and second annealing/cooling module 104B. The single wafer deposition chambers 102A, 102B and 102C can be adopted to deposit various materials using any type of deposition technique. For example and when a multilayered diffusion barrier is used, the first deposition chamber 102A can be used in the present disclosure for depositing a first component of the diffusion barrier 16, the second deposition chamber 102B can be used in forming a second component of the diffusion barrier, and the third deposition chamber 102C can be used for depositing the metal liner 18. Each annealing/cooling module 104A, 104B may contain an annealing chamber 106A, 106B and an adjacent cooling chamber 108A, 108B.

The multi-chambered processing system 100 of the present disclosure may also include a loading/unloading chamber 101, preclean chambers 110A, 110B, degas chambers 112A, 112B and robots such as first robot 114A and second robot 114B, which may be connected to each other via a transfer chamber 116. Although two annealing/cooling modules, two degassing chambers and two pre clean chambers are described and illustrated, the multi-chambered processing system 100 is not limited to that number of annealing/cooling modules, degassing chambers and pre clean chambers. Instead, it is possible to have one of each of annealing/cooling module, degassing chamber and pre clean chamber within the multi-chambered system of the present disclosure.

As shown in FIG. 7, the first robot 114A can be used to transfer samples between the load/unloading chamber 101, and the various annealing/cooling modules 104A, 104B, degas chambers 112A, 112B and transfer chamber 116. The second robot 114B can be used to transfer the samples between the various deposition chambers 102A, 102B, and 102C, pre clean chambers 110A, 110B and the transfer chamber 116. In one embodiment of the present disclosure, the first robot 114A and the second robot 114B rotate about the various chambers that are coupled with the individual robots.

In accordance with the present disclosure and as stated above, the multi-chambered processing system 100 is operated under a continuous vacuum, i.e., vacuum is maintained throughout the various depositions and reflow anneal. As such, once the sample is placed into the loading/unloading chamber 101 the system is locked and a vacuum is applied to obtain a desired pressure within the system.

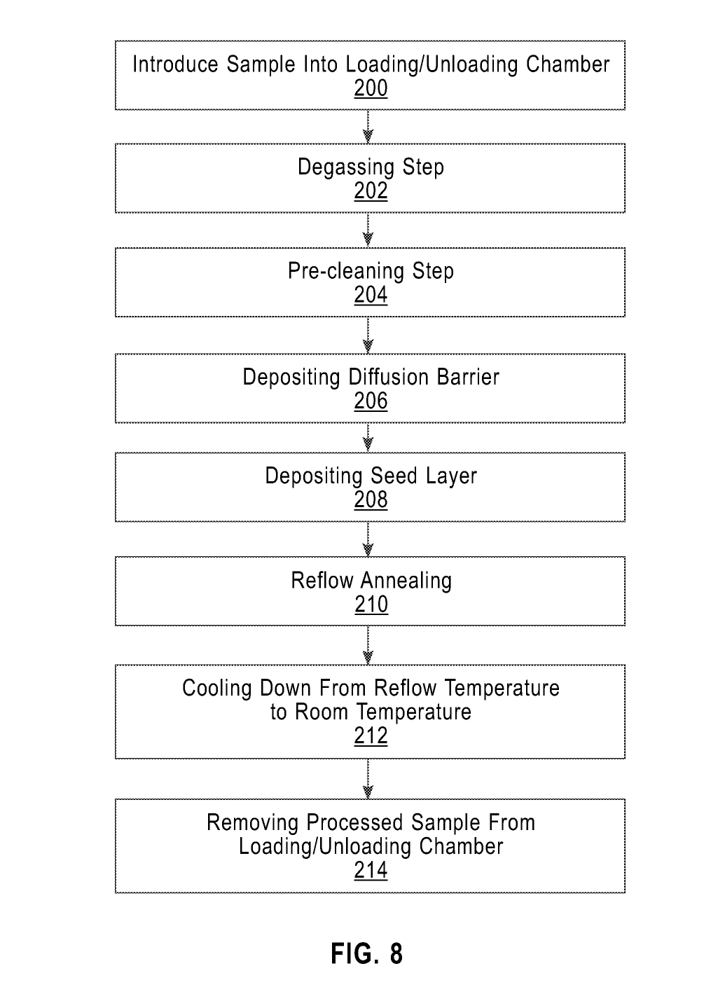

Reference is now made to FIG. 8, which is a flow diagram of one embodiment of the present disclosure for forming an interconnect structure using the multi-chambered processing system shown in FIG. 7. This embodiment of the present disclosure begins by a step 200 of introducing a sample, such as the one depicted in FIG. 2 into the loading/unloading chamber 101 of multi-chambered processing system 100. Once the sample is introduced into the loading/unloading chamber 101, the multi-chambered processing system 100 is locked and a vacuum is provided to achieve a desired pressure within the multi-chambered processing system 100. In one embodiment, a vacuum is provided to provide a pressure from 10⁻⁵ Torr to 10⁻¹⁰ Torr within the multi-chambered processing system 100. In another embodiment of the present disclosure, a vacuum is provided to provide a pressure from 10⁻⁷ Ton to 10⁻⁸ Torr within the multi-chambered processing system 100.

Once the desired pressure within the system is achieved, the sample is transferred from the loading/unloading chamber 101 to one of the degas chambers 112A, 112B using first robot 114A. Once within one of the degas chambers 112A, 112B, the sample is then subjected to a degassing step 202. Degassing step 202 can be performed in an inert ambient such as, for example, Ar, Ne, He and mixtures thereof which can be introduced into the degas chamber including the sample via a gas inlet line (not shown). In one embodiment of the present disclosure, the degas step 202 is performed in the inert ambient at a temperature from 100° C. to 500° C. In other embodiments, the degassing step 202 is performed at a temperature that is lesser than or greater than the aforementioned temperature range. The degassing step 202 removes unwanted gases such as, for example, organic residues from the sample which if not removed could affect the adhesion of the materials to be subsequently deposited.

After performing degas step 202, the now degassed sample is removed from the degas chamber 112A, 112B and transferred to transfer chamber 116 by the first robot 114A. Second robot 114B is then used to transfer the degassed sample from the transfer chamber 116 to one of the pre clean chambers 110A, 110B. Once transferred to one of the pre clean chambers 110A, 110B, the degassed sample is subjected to pre-cleaning step 204. The pre-cleaning step 204 is performed in hydrogen and/or helium and/or argon which can be introduced into one of the pre clean chambers 110A, 110B via a gas inlet line (not shown). In one embodiment of the present disclosure, the pre clean is performed within the hydrogen and/or nitrogen and/or argon ambient at a temperature from 50° C. to 400° C. In other embodiments, the pre-cleaning step 204 is performed at a temperature that is lesser than or greater than the aforementioned temperature range. The pre-cleaning step 204 removes unwanted surface contaminants such as, for example, oxides from the sample which if not removed could affect the adhesion of the materials to be subsequently deposited.

After performing pre-cleaning step 204, the now degassed and cleaned sample is ready for deposition. In one embodiment, the degassed and cleaned sample is transferred from the pre clean chamber to the first deposition chamber 102A by second robot 114B. Once within the first deposition chamber 102A, the sample can be subjecting to a step 206 of depositing a diffusion barrier material. The diffusion barrier material used in step 206 includes one of the materials mentioned above for diffusion barrier 16. Also, one of the above mentioned deposition processes mentioned above for providing diffusion barrier 16 can be used herein within step 206. The deposition of the diffusion barrier material, i.e., diffusion barrier 16, can be performed at a temperature from room temperature (i.e., 20° C.) to 400° C. Other temperatures that are lesser than or greater than the aforementioned temperatures can also be used to deposit the diffusion barrier material, i.e., diffusion barrier 16.

Once the diffusion barrier 16 has been deposited, second robot 114B is used to transfer the sample now including diffusion barrier 16 from the first deposition chamber 102A to a second deposition chamber 102B. Within the second deposition chamber 102B, a step 208 of depositing a metal liner 18 can be performed. The metal liner used in step 208 includes one of the materials mentioned above for metal liner 18. Also, PVD as mentioned above for providing metal liner 18 can be used herein within step 208. The deposition of the metal liner 18, can be performed at a temperature from room temperature (i.e., 20° C.) to 400° C. Other temperatures that are lesser than or greater than the aforementioned temperatures can also be used to deposit the metal liner 18.

After the metal liner 18 has been deposited, second robot 114B is again used to transfer the sample now including a metal liner/diffusion barrier stack from the second deposition chamber 102B to the transfer chamber 116. An optional pre clean step as described above may be performed between each of the aforementioned deposition processes. The sample including the metal liner/diffusion barrier stack is then transferred from the transfer chamber 116 into one of the anneal chambers 106A, 106B of one of the annealing/cooling modules 104A, 104B using first robot 114A. After entry into one of the annealing chambers 106A, 106B, a step 210 of reflow annealing, as described above, can be performed.

In one embodiment of the present disclosure, the annealing chamber 106A, 106B in which step 210, i.e., reflow annealing, is performed is held at room temperature (i.e., 20° C.) and the above steps 200, 202, 204, 206 and 208 can be repeated any number of times until a desired number of samples that include a metal liner/diffusion barrier stack are accumulated within the annealing chamber 106A, 106B. When the desired number of samples that include a metal liner/diffusion barrier stack is accumulated within the annealing chamber 106A, 106B, the temperature within the annealing chamber is raised from room temperature up to a desired reflow anneal temperature as described above.

In another embodiment, a single sample including the metal liner/diffusion barrier stack is subjected to reflow annealing as described above.

The annealed sample (or samples) are then subjected to a step 212 of cooling down from the reflow anneal temperature to room temperature within an adjacent cooling chamber 108A, 108B. The step of cooling 212 is performed in an inert ambient such as, for example, He, Ar, Ne and mixtures thereof. The cooled sample (or samples) is (are) then transferred from the cooling chamber 108A, 108B to the loading/unloading chamber 101 by first robot 114A. The sample (or samples) is (are) then removed (in step 214) from the multi-chambered processing system and are then ready for further processing.

Referring now to FIG. 9, there is illustrated the structure of FIG. 5 after performing a planarization process. The planarization process which can be employed in the present disclosure includes, for example, chemical mechanical polishing (CMP) and/or grinding. The planarization process removes materials that extend out of the opening 14 and atop an uppermost surface of the interconnect dielectric material. Typically, a portion of the conductive metal 20 and a portion of the diffusion barrier 16 are removed from atop the uppermost surface of the interconnect dielectric material 12 during the planarization process.

While the present disclosure has been particularly shown and described with respect to preferred embodiments thereof, it will be understood by those skilled in the art that the foregoing and other changes in forms and details may be made without departing from the spirit and scope of the present disclosure. It is therefore intended that the present disclosure not be limited to the exact forms and details described and illustrated, but fall within the scope of the appended claims.

1. A method for forming an interconnect structure comprising:
providing an interconnect dielectric material having at least one opening;
placing the interconnect dielectric material having the at least one opening within a multi-chambered processing system;
performing a pre-cleaning step in a pre-cleaning chamber of said multi-chambered processing system and on said interconnect dielectric material at a temperature from 50° C. to 400° C., wherein said pre-cleaning step removes surface oxides from said interconnect dielectric material;
depositing at least a metal liner comprising a conductive metal or conductive metal alloy above an uppermost surface of the interconnect dielectric material and in the at least one opening, wherein said depositing is performed in a deposition chamber of said multi-chambered processing system; and
performing a reflow anneal within an annealing chamber of said multi-chambered processing system, wherein said reflow anneal flows a portion of the metal liner located above the uppermost surface of the interconnect dielectric material into the at least one opening and fills said at least one opening with said conductive metal or conductive metal alloy, wherein a continuous vacuum of from 10⁻⁵ to 10⁻¹⁰ Torr is maintained during said pre-cleaning, said depositing and said reflow anneal.

2. The method of claim 1, further comprising depositing a diffusion barrier prior to depositing said metal liner.

3. The method of claim 2, wherein said depositing said diffusion barrier is performed in another deposition chamber of said multi-chambered processing system, and wherein said depositing of said diffusion barrier and said metal liner and said reflow anneal are performed under said continuous vacuum.

4. The method of claim 2, wherein said depositing said seed layer metal liner comprises physical vapor deposition.

5. The method of claim 1, wherein said multi-chambered processing system further includes a loading/unloading chamber and a transfer chamber coupled to said at least one deposition chamber and said at least one annealing chamber, wherein a first robot is present for transferring said interconnect dielectric material from said loading/unloading chamber into said transfer chamber, and wherein a second robot is present for transferring said interconnect dielectric material from said transfer chamber to said at least one deposition chamber.

6. The method of claim 1, wherein a degassing step is performed prior to said depositing the at least metal liner, and said degassing step is performed in an inert ambient and at a temperature from 100° C. to 500° C.

7. The method of claim 1, wherein another pre-cleaning step is performed between said depositing the at least metal liner and said reflow anneal, wherein said another pre-cleaning step is performed in an inert ambient and at a temperature from 50° C. to 400° C. and removes surface oxide from said metal liner.

8. The method of claim 1, wherein said reflow anneal is performed at a temperature from 150° C. to 400° C.

9. The method of claim 8, wherein said reflow anneal is performed in a hydrogen ambient, a nitrogen-ambient or a combination of hydrogen and nitrogen ambients.

10. The method of claim 1, wherein said metal liner comprises copper, tungsten, aluminum or alloys thereof.

11. The method of claim 1, further comprising performing a planarizing process after performing said reflow anneal.

12. The method of claim 1, wherein prior to performing said reflow annealing the steps of providing the interconnect dielectric material having at least one opening, placing the interconnect dielectric material having the at least one opening within the multi-chambered processing system, and depositing at least the metal liner are performed to provide a plurality of structures including said metal liner, and then performing said reflow anneal on each of said structures of the plurality of structures.

13. The method of claim 2, wherein said diffusion barrier is selected from the group consisting of Co, Ir, Pt, Pd, Ta, Rh, TaN, Ti, Ru, SuN, RuTa, RuTaN, W and WN.

14.-21. (canceled)

22. The method of claim 1, wherein said metal liner has a bare upper surface prior to and during said reflow anneal.

23. The method of claim 1, wherein said pre-cleaning step is performed in hydrogen or a mixture of hydrogen and at least one of helium and argon.

24. A method for forming an interconnect structure comprising:
providing an interconnect dielectric material having at least one opening;
placing the interconnect dielectric material having the at least one opening within a multi-chambered processing system;
performing a first pre-cleaning step at a temperature from 50° C. to 400° C. and in a pre-cleaning chamber of said multi-chambered processing system, wherein said first pre-cleaning step removes surface oxides from said interconnect dielectric material;
depositing at least a metal liner comprising a conductive metal or conductive metal alloy above an uppermost surface of the interconnect dielectric material and in the at least one opening, wherein said depositing is performed in a deposition chamber of said multi-chambered processing system;
performing a second pre-cleaning step at a temperature from 50° C. to 400° C. in said pre-cleaning chamber, wherein said second pre-cleaning step removes surface oxide from said metal liner; and
performing a reflow anneal within an annealing chamber of said multi-chambered processing system, wherein said reflow anneal flows a portion of the metal liner located above the uppermost surface of the interconnect dielectric material into the at least one opening and fills said at least one opening with said conductive metal or conductive metal alloy, wherein a continuous vacuum of from 10⁻⁵ to 10⁻¹⁰ Torr is maintained during said first pre-cleaning, said second pre-cleaning, said depositing and said reflow anneal.

25. The method of claim 24, wherein said second pre-cleaning step is performed in hydrogen or a mixture of hydrogen and at least one of helium and argon.

26. The method of claim 24, wherein said second pre-cleaning step is performed in helium, argon or a mixture of helium and argon.

27. The method of claim 1, wherein said metal liner has a bare upper surface prior to and during said reflow anneal.
